(19) United States
(12) Patent Application Publication
(10) Pub. No.: US 2026/0086689 A1
(43) Pub. Date: Mar. 26, 2026

(54) SENSOR, POSITION DETECTION APPARATUS, AND SENSOR CONTROLLER

(71) Applicant: Wacom Co., Ltd., Saitama (JP)

(72) Inventors: Hayato KURASAWA, Saitama (JP); Yue MA, Saitama (JP)

(73) Assignee: Wacom Co., Ltd., Saitama (JP)

(21) Appl. No.: 19/339,992

(22) Filed: Sep. 25, 2025

(30) Foreign Application Priority Data
Sep. 26, 2024 (JP) 2024-167945

(51) Int. Cl. G06F 3/046; G06F 3/041; G06F 3/044

(52) U.S. Cl. CPC G06F 3/046; G06F 3/04164; G06F 3/044; G06F 2203/04102; G06F 2203/04106; G06F 2203/04114

(57) ABSTRACT

Provided is a sensor including an outside loop coil having a first end and a second end, where the first end of the outside loop coil is connected to a first output terminal, and an inside loop coil having a first end and a second end, wherein the first end of the inside loop coil is connected to a second output terminal. The second end of the outside loop coil and the first end of the inside loop coil are connected to each other by a bridge conductor that straddles the inside loop coil.

### BACKGROUND

### Technical Field

The present disclosure pertains to a sensor, a position detection apparatus, and a sensor controller, and particularly pertains to a sensor, a position detection apparatus, and a sensor controller that are used to detect the position of a pen by using an electromagnetic resonance method (EMR method).

### Description of the Related Art

There is known a position detection apparatus that detects the position of a pen by using an EMR method. Japanese Patent Laid-open No. 2019-211887 and Japanese Patent Laid-open No. 2017-174083 (hereinafter respectively referred to as “Patent Document 1” and “Patent Document 2”) disclose examples of this type of position detection apparatus. As disclosed in Patent Documents 1 and 2, this type of position detection apparatus has a sensor which includes a plurality of loop coils and a sensor controller that is an integrated circuit for detecting the position of the pen by using this sensor. The sensor controller sends an alternating magnetic field (referred to as a “sensor alternating magnetic field” below) from a touch surface by supplying an alternating current to any single loop coil and receives, at each loop coil, an alternating magnetic field (referred to as a “pen alternating magnetic field” below) sent from a resonant circuit in a pen that is inside the sent sensor alternating magnetic field, to thereby fulfill a role of detecting the position of the pen within the touch surface.

Patent Document 2 discloses employing a loop coil (referred to as a “receiving coil” below) for receiving a pen alternating magnetic field as a mesh electrode and employing a coil having 1.5 or two or more windings for the receiving coil.

Incidentally, the sending intensity of the pen alternating magnetic field is weak. Hence, in the EMR method, a sensor that can receive the pen alternating magnetic field at high sensitivity is required. In relation to this problem, if the number of windings of a receiving coil is set to two or more as in the idea disclosed in Patent Document 2, it is possible to sufficiently improve the sensitivity of receiving the pen alternating magnetic field. However, with a conventional EMR method, 1.5 windings as with the receiving coil disclosed in Patent Literature 2 is the limit, and realizing two or more windings has not been possible.

### BRIEF SUMMARY

Accordingly, one objective of the present disclosure is to provide a sensor having a receiving coil with two windings, a position detection apparatus, and a sensor controller.

In addition, the present inventors considered setting a receiving coil to be a comb-shaped coil (a coil having a shape in which a plurality of comb teeth protrude from one linear base section). By virtue of a comb-shaped coil, usage in a time-divisional fashion becomes necessary, but it is possible to configure N−1 receiving coils by N comb teeth. Thus, it becomes possible to reduce the area of wiring for the receiving coils in comparison to a case of using N−1 square U-shaped receiving coils. However, individual receiving coils that are realized by the comb-shaped coil inevitably have one winding. Therefore, reception sensitivity for a pen alternating magnetic field could not be said to be sufficient.

Accordingly, one other objective of the present disclosure is to provide a sensor and a position detection apparatus that can improve the reception sensitivity of a receiving coil while utilizing the advantages of a comb-shaped coil.

In addition, in a case where a receiving coil is configured by a mesh electrode as described in Patent Document 2, an advantage of improving the visibility for a display that is overlappingly disposed on a sensor is achieved, but there is a problem that the wire becomes thinner in comparison to a case of configuring the receiving coil by a flat plate-shaped flat electrode and the direct-current resistance of the receiving coil thus increases.

Accordingly, yet another objective of the present disclosure is to provide a sensor that is configured by a mesh electrode but can realize a receiving coil having a direct-current resistance lower than that of a conventional receiving coil configured by a mesh electrode.

In addition, electronic devices having a shape resulting from lining up two screens in a lateral direction (referred to as a “two-screen electronic device” below) have been developed in recent years, but in a case where this type of electronic device is caused to support the EMR method, a receiving coil that extends in the lateral direction is divided by each screen. Therefore, the required number thereof is doubled, and the required number of receiving circuits is also doubled.

Accordingly, yet another objective of the present disclosure is to provide a sensor that enables the required number of receiving circuits in a two-screen electronic device to be reduced.

A sensor according to a first aspect of the present disclosure, includes an outside loop coil having a first end and a second end, wherein the first end of the outside loop coil is connected to a first output terminal, and an inside loop coil having a first end and a second end connected to a second output terminal, the other end of the outside loop coil and one end of the inside loop coil being connected to each other by a bridge conductor that straddles the inside loop coil.

In addition, a position detection apparatus according to the first aspect of the present disclosure includes the sensor according to the first aspect of the present disclosure, and a switch circuit that, in operation, switches between a first state in which the first output terminal and the second output terminal are connected to each other and a second state in which the first output terminal and the second output terminal are respectively connected to a first input terminal and a second input terminal of a same differential amplifier.

In addition, a sensor controller according to the first aspect of the present disclosure uses the sensor according to the first aspect of the present disclosure to detect a position of an electromagnetic resonance pen or a passive pointer, the sensor controller controlling a switch being configured to switch between a first state in which the first output terminal and the second output terminal are connected to each other and a second state in which the first output terminal and the second output terminal are respectively connected to a first input terminal and a second input terminal of a same differential amplifier.

A sensor according to a second aspect of the present disclosure includes a loop coil that includes a plurality of wires, wherein each of the plurality of wires extends in a first direction, wherein each of the plurality of wires includes a plurality of main wire sections, wherein each of the plurality of main wire sections is configured by a plurality of linear partial wires, and a plurality of connection sections, wherein each of the plurality of connection sections connects two of the main wire sections that are adjacent to each other, and wherein one of the plurality of linear partial wires that configure a first one of the main wire sections also serves as one of the plurality of linear partial wires that configure a second one of the main wire sections that is adjacent inside a same one of the wires.

A sensor according to a third aspect of the present disclosure includes a composite coil having three or more output terminals, wherein the composite coil includes a plurality of partial coils, wherein each of the partial coils corresponds to one of output terminals, wherein each of the partial coils is formed with one or more windings, wherein a first end of each of the partial coils is connected to a corresponding one of the output terminals, and wherein a second end of each of the partial coils is connected to another one of the partial coils that is adjacent.

A sensor according to a fourth aspect of the present disclosure includes a comb-shaped coil that includes a base section that extends in a first direction and a plurality of comb teeth, wherein each of the plurality of comb teeth extends in a second direction that intersects with the first direction, wherein a first end of each of the plurality of comb teeth is connected to the base section, and wherein a second end of each of the plurality of comb teeth configures an output terminal, and a plurality of loop coils, wherein each of the plurality of loop coils is provided between two adjacent comb teeth.

A position detection apparatus according to the fourth aspect of the present disclosure includes the sensor according to the fourth aspect of the present disclosure, a switch that, in operation, switches between a first mode for detecting a position of a pen by an electromagnetic resonance method and a second mode for detecting a position of a passive pointer by a capacitance method, and a differential amplifier, wherein, in the first mode, the switch configures a state in which a two-winding coil is connected to the differential amplifier by connecting one end of one of the loop coils with a first one of the two output terminals that correspond to the one of the loop coils and connecting a second end of the one of the loop coils and a second one of the two output terminals that correspond to the loop coil with the differential amplifier.

A sensor according to a fifth aspect of the present disclosure is disposed inside a first panel surfaces and a second panel surface arranged lined up in a first direction, the sensor including a first coil that extends along the first direction inside the first panel surface, and a second coil that extends along the first direction inside the second panel surface, the first coil and the second coil being connected in parallel or in series to a same differential amplifier.

By virtue of the first aspect of the present disclosure, it is possible to provide a sensor that has a two-winding receiving coil. In addition, it becomes possible to use this sensor in both the capacitance method and the EMR method.

By virtue of the second aspect of the present disclosure, it is possible to realize a receiving coil that is configured by a mesh electrode but has a direct-current resistance lower than that of a conventional receiving coil configured by a mesh electrode.

By virtue of the third and fourth aspects of the present disclosure, it becomes possible to improve the reception sensitivity of a receiving coil while utilizing the advantages of a comb-shaped coil.

By virtue of the fifth aspect of the present disclosure, the first coil and the second coil are connected in parallel or in series to one differential amplifier (receiving circuit). Therefore, it becomes possible to reduce the required number of receiving circuits in a two-screen electronic device.

### BRIEF DESCRIPTION OF THE SEVERAL VIEWS OF THE DRAWINGS

FIG. 1 is a view that illustrates a configuration of a position detection system according to a first embodiment of the present disclosure;

FIG. 2 is a view that illustrates a typical configuration of first and second electrodes and an internal configuration of a switch unit;

FIG. 3 is a view that illustrates a typical configuration of the first and second electrodes, and an internal configuration of the switch unit;

FIG. 4 is a view that illustrates a configuration of a sensor, a flexible substrate, and the switch unit that are included in the position detection system according to the first embodiment of the present disclosure;

FIG. 5 is a view that illustrates a configuration of a sensor, a flexible substrate, and a switch unit that are included in a position detection system 1 according to a first variation of the first embodiment of the present disclosure;

FIG. 6 is a view that illustrates a configuration of a sensor, a flexible substrate, and a switch unit that are included in a position detection system 1 according to a second variation of the first embodiment of the present disclosure;

FIGS. 7A and 7B are views that illustrate a configuration of a sensor that is included in a position detection system according to a second embodiment of the present disclosure;

FIGS. 8A and 8B are views that illustrate a configuration of a sensor that is included in a position detection system according to a variation of the second embodiment of the present disclosure;

FIGS. 9A and 9B are views that illustrate a configuration of a sensor, a flexible substrate, and a switch unit that are included in a position detection system according to a third embodiment of the present disclosure;

FIG. 10 is a view that illustrates a configuration of the sensor, the flexible substrate, and the switch unit that are included in the position detection system 1 according to the third embodiment of the present disclosure;

FIG. 11A is a view that illustrates a case in which a plurality of first electrodes that are included in a sensor are configured by a comb-shaped coil, and FIG. 11B is a view that illustrates a case in which the plurality of first electrodes that are included in the sensor are configured by a composite coil;

FIG. 12A is a view that illustrates a case in which a plurality of first electrodes that are included in a sensor are configured by a comb-shaped coil, and FIG. 12B is a view that illustrates a case in which the plurality of first electrodes that are included in the sensor are configured by a composite coil;

FIG. 13A is a view that illustrates the strength of sensor alternating magnetic fields that have been sent in the manner illustrated in FIGS. 11A and 11B, and FIG. 13B is a view that illustrates the strength of sensor alternating magnetic fields that have been sent in the manner illustrated in FIGS. 12A and 12B;

FIGS. 14A and 14B are views that illustrate a configuration of a sensor, a flexible substrate, and a switch unit that are included in a position detection system according to a fourth embodiment of the present disclosure;

FIG. 15 is a view that illustrates a configuration of the sensor, the flexible substrate, and the switch unit that are included in the position detection system according to the fourth embodiment of the present disclosure;

FIGS. 16A and 16B are views that illustrate a configuration of sensors and a switch unit that are included in a position detection system according to a fifth embodiment of the present disclosure;

FIGS. 17A and 17B are views that illustrate a configuration of sensors and a switch unit that are included in a position detection system according to a first variation of the fifth embodiment of the present disclosure;

FIGS. 18A and 18B are views that illustrate a configuration of sensors and a switch unit that are included in a position detection system according to a second variation of the fifth embodiment of the present disclosure; and

FIGS. 19A and 19B are views that illustrate a configuration of sensors and a switch unit that are included in a position detection system according to a third variation of the fifth embodiment of the present disclosure.

### DETAILED DESCRIPTION

With reference to the attached drawings, description is given in detail below regarding embodiments of the present disclosure.

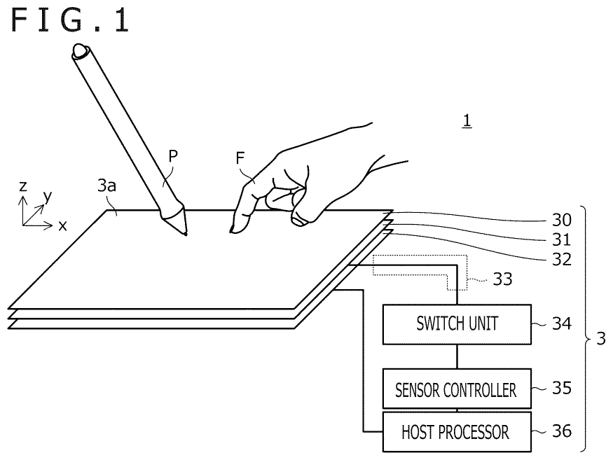

FIG. 1 is a view that illustrates a configuration of a position detection system 1 according to a first embodiment of the present disclosure. As illustrated in FIG. 1, the position detection system 1 is provided with an electromagnetic resonance pen P and a position detection apparatus 3. Among these, the electromagnetic resonance pen P is a pen (indicator) that supports position detection using the EMR method, and is provided with a resonant circuit that includes a coil and a capacitor therein.

The position detection apparatus 3 is an electronic device that supports detecting the position of the electromagnetic resonance pen P by the EMR method and detecting the position of a passive pointer by a capacitance method. A finger F illustrated in FIG. 1 is an example of a passive pointer. A position detection apparatus 3 according to a typical example is a type of computer for which a touch surface also serves as a display surface: a laptop computer, a tablet terminal, a smartphone, or the like, for example. The position detection apparatus 3 will continuously be described below as such a type of computer, but the present disclosure can also be applied to a type of position detection apparatus for which a touch surface does not serve as a display surface, such as a digitizer, for example.

The position detection apparatus 3 includes cover glass 30, a sensor 31, a display 32, a flexible substrate 33, a switch unit 34, a sensor controller 35, and a host processor 36.

The cover glass 30 is plate-shaped glass that covers the entirety of the sensor 31 and the display 32, and a surface thereof configures a panel surface 3a for the position detection apparatus 3. In the position detection apparatus 3, this panel surface 3a serves as both a touch surface and a display surface, and the position detection apparatus 3 is configured to be able to detect the positions of the electromagnetic resonance pen P and the passive pointer on the panel surface 3a.

The sensor 31 supports both detecting the position of the electromagnetic resonance pen P by the EMR method and detecting the position of the passive pointer by the capacitance method, and has a plurality of first electrodes that are each formed in such a manner as to extend in an illustrated x direction and are arranged to line up in an illustrated y direction and a plurality of second electrodes that are each formed in such a manner as to extend in the y direction and are arranged to line up in the illustrated x direction. The sensor 31 has a multi-layer structure, and the plurality of first electrodes and the plurality of second electrodes are formed in layers that are different from each other. Electrically, each of the first electrodes and each of the second electrodes are connected to the sensor controller 35 via wiring inside the flexible substrate 33 and a switch inside the switch unit 34.

Each first electrode is typically a linear electrode, but may be a loop-shaped electrode (referred to as a “loop coil” below). In addition, the plurality of first electrodes may be configured using comb-shaped coils (coils having a shape resulting from connecting a plurality of comb teeth that each extend in the y direction from one base section extending in the x direction). In this case, a plurality of switches for separating the comb teeth are provided to the base section in advance, and, when detecting a passive pointer, these switches are turned off, whereby each comb tooth is used as an independent linear electrode.

Each second electrode typically is a loop coil, but the plurality of second electrodes may be configured using comb-shaped coils, similarly to the plurality of first electrodes. In this case as well, a plurality of switches for separating the comb teeth are provided to the base section in advance, and, when detecting a passive pointer, these switches are turned off, whereby each comb tooth is used as an independent linear electrode. One feature of the position detection apparatus 3 according to the present embodiment is the structure of the second electrodes, but details thereof are described later.

The display 32 is a display apparatus for displaying, on the panel surface 3a, a video signal supplied from the host processor 36. A specific method for the display 32 is not limited to any kind, but may be a liquid-crystal display or an organic electroluminescence (EL) display, for example.

The switch unit 34 is a circuit that includes a plurality of switches for switching connections between the sensor controller 35 and each of the plurality of first electrodes and second electrodes that configure the sensor 31. An operational amplifier 34f and a differential amplifier 34g, which are described later, are also provided within the switch unit 34. The switch unit 34 may be provided within a dedicated circuit board or integrated circuit, or may be provided within the same integrated circuit as the sensor controller 35. A switching state for the switch unit 34 is controlled by the sensor controller 35. Details of the switch unit 34 are also described below.

The sensor controller 35 is an integrated circuit that has a function for using the EMR method to detect the position of the electromagnetic resonance pen P on the panel surface 3a and a function for using the capacitance method to detect the position of the passive pointer on the panel surface 3a. In relation to the electromagnetic resonance pen P, the sensor controller 35 also has a function for obtaining data transmitted by the electromagnetic resonance pen P by demodulating the pen alternating magnetic field sent by the electromagnetic resonance pen P. Detecting the position of the electromagnetic resonance pen P, obtaining data from the electromagnetic resonance pen P, and detecting the position of the passive pointer are time-divisionally executed. The sensor controller 35 is configured to successively supply the host processor 36 with detected positions and obtained data. In one or more implementations, the sensor controller 35 includes a processor and a memory storing instructions that, when executed by the processor, cause the sensor controller 35 to perform the acts described herein.

The host processor 36 is the central processing unit in the position detection apparatus 3, and is configured to execute a program stored in an unillustrated memory to be able to execute an operating system for the position detection apparatus 3 or various types of applications. In addition, the host processor 36 also performs a process for generating a video signal that corresponds to a result of executing an application, and supplying the video signal to the display 32.

A program executed by the host processor 36 includes that for performing a process based on a position and data that are supplied to the host processor 36 from the sensor controller 35. This process includes, inter alia, movement of a cursor that is being displayed on the panel surface 3a and generation of stroke data that indicates the path of the electromagnetic resonance pen P or the passive pointer on the panel surface 3a. In relation to stroke data among these, the host processor 36 is configured to be able to execute, inter alia, a process for rendering and displaying generated stroke data, a process for generating and recording digital ink that includes the generated stroke data, and a process for transmitting the generated digital ink to an external apparatus in response to an instruction from a user.

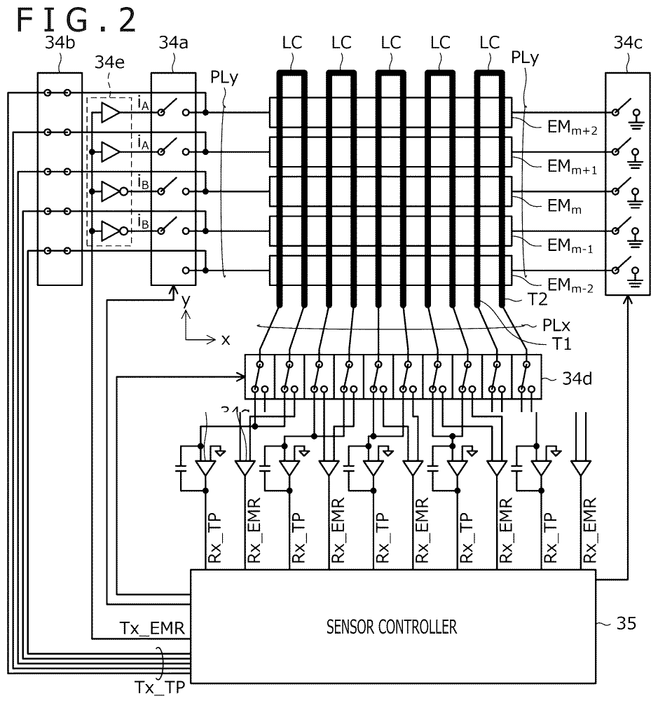

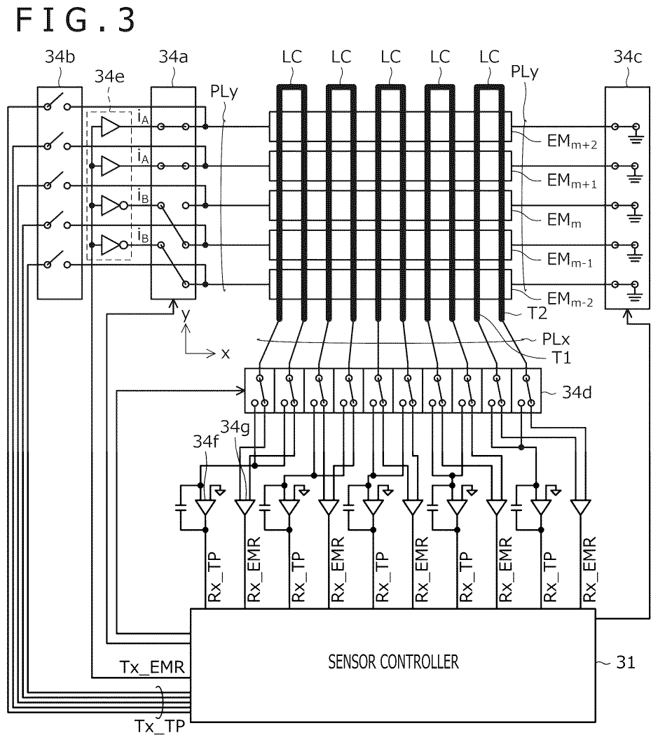

FIG. 2 and FIG. 3 are views that illustrate a typical configuration of the first and second electrodes described above and an internal configuration of the switch unit 34. FIG. 2 and FIG. 3 illustrate an example in which the first electrodes are linear electrodes EM and the second electrodes are one-winding loop coils LC. For simplicity, FIG. 2 and FIG. 3 illustrate five loop coils LC and five linear electrodes EMₘ₋₂ through EMₘ₊₂, but the actual position detection apparatus 3 has more loop coils LC and linear electrodes EM. In addition, FIG. 2 illustrates a state of the switch unit 34 for a case in which the sensor controller 35 detects the position of the passive pointer, and FIG. 3 illustrates a state of the switch unit 34 for a case in which the sensor controller 35 detects the position of the electromagnetic resonance pen P.

As illustrated in FIG. 2 and FIG. 3, the switch unit 34 includes four types of switches 34a through 34d, a drive circuit 34c, a plurality of operational amplifiers 34f, and a plurality of differential amplifiers 34g.

The switch 34a is configured to supply an alternating current Tx_EMR for generating a sensor alternating magnetic field on the panel surface 3a to the plurality of linear electrodes EM, and has four input pins that are connected to the drive circuit 34c and an output pin that is provided for each linear electrode EM. Each output pin is connected, via a let-out line PLy, to one end in the x direction of the corresponding linear electrode EM. The switch 34a fulfills a role of connecting each input pin with one output pin, in response to control by the sensor controller 35.

The drive circuit 34e generates alternating currents i_{A} and is in response to the alternating current Tx_EMR supplied from the sensor controller 35, and supplies the alternating currents i_{A} and i_{B} to the linear electrodes EM via the switch 34a. The drive circuit 34e is configured to supply the alternating current i_{A} to two out of the four input pins for the switch 34a, and supply the alternating current is to the other two input pins.

The alternating current i_{A} is, for example, generated by using a buffer circuit to amplify the alternating current Tx_EMR. In contrast, the alternating current i_{B} is generated in order to satisfy a relation in which the time derivatives of the alternating current i_{B} and the alternating current i_{A} have a phase opposite to one another. When this relation is represented by an equation, the following formula (1) is achieved. The relation in formula (1) may be said to be a relation in which an amount of decrease for the alternating current is increases in conjunction with an amount of increase for the alternating current is increasing and an amount of increase for the alternating current i_{B} increases in conjunction with an amount of decrease for the alternating current is increasing, or may be said to be a relation in which an amount of increase of the potential at one end with respect to the other end in the longitudinal direction for each of one or more linear electrodes EM to which the alternating current i_{B} is supplied increases in conjunction with an amount of increase in the potential of the other end with respect to the one end in the longitudinal direction for each of one or more linear electrodes EM to which the alternating current i_{A} is supplied increasing.

$$\begin{matrix}[ Formula 1 ] & \\ \frac{{di}_{A} ( t )}{dt} = - \frac{{di}_{B} ( t )}{dt} & ( 1 )\end{matrix}$$

A typical alternating current is that satisfies the relation in formula (1) is expressed by the following formula (2). However, A is any defined constant. In a case where A=0, the alternating current is becomes the inverted signal of the alternating current i_{A}. In this case, the alternating current iA and the alternating current i_{B} will have signs different from each other. In contrast, in a case where A is greater than the maximum value of the alternating current i_{A}, the alternating current i_{A} and the alternating current i_{B} will have the same sign but will be at levels that are different from one another. Note that an inverted signal for the alternating current i_{A} can be generated using an inverting buffer circuit, for example. FIG. 2 and FIG. 3 illustrate an example in which this inverting buffer circuit is used.

$$\begin{matrix}[ Formula 2 ] & \\ {i}_{B} ( t ) = - {i}_{A} ( t ) + A & ( 2 )\end{matrix}$$

It is desirable for the potential of the other end of each linear electrode EM that is supplied with the alternating current i_{A} or is to be set to the potential at a midpoint between the potential that arises at one end of a linear electrode EM that is supplied with the alternating current i_{A} and the potential that arises at one end of a linear electrode EM that is supplied with the alternating current i_{B}. In a case where A=0, this potential becomes 0 (in other words, ground potential).

The switch 34b is configured to supply the plurality of linear electrodes EM with a touch detection signal Tx_TP for detecting the position of the passive pointer, and has a set of an input pin and an output pin that is provided for each linear electrode EM. Each input pin is supplied with the touch detection signal Tx_TP from the sensor controller 35. Each output pin is connected to the corresponding linear electrode EM via a let-out line PLy. The switch 34b fulfills a role of connecting each input pin with the corresponding output pin, in response to control by the sensor controller 35.

The switch 34c is configured to, for the other end of a linear electrode EM in the x direction, switch between a state of being connected to the above-described midpoint potential and a floating state of not being connected to anywhere. FIG. 2 and FIG. 3 illustrate a case in which the above-described midpoint potential is the ground potential, and the switch 34c in this case has a set of an input pin and a ground pin that is provided for each linear electrode EM. The description continues below under the premise that the above-described midpoint potential is the ground potential.

Each input pin in the switch 34c is connected, via a let-out line PLy, to the other end in the x direction of the corresponding linear electrode EM. In contrast, each ground pin in the switch 34c is connected to a ground end to which the ground potential is supplied. The reason why the switch 34c is provided is because it is desirable to set the other end of each linear electrode EM in the x direction to the ground potential as described above when the sensor controller 35 detects the position of the electromagnetic resonance pen P, but it is necessary to set the other end of each linear electrode EM in the x direction to the floating state when the sensor controller 35 detects the position of the passive pointer. The switch 34c fulfills a role of switching connection states between each input pin and the corresponding ground pin, in response to control by the sensor controller 35.

The switch 34d is configured to supply a differential amplifier 34g with the alternating current that arises due to the pen alternating magnetic field (the pen alternating magnetic field generated by the electromagnetic resonance pen P in response to the sensor alternating magnetic field generated by the alternating current Tx_EMR) detected by each loop coil LC when the sensor controller 35 detects the position of the electromagnetic resonance pen P, but supply an operational amplifier 34f with the touch detection signal Tx_TP received by the loop coil LC when the sensor controller 35 detects the position of the passive pointer.

To give a description in detail, the switch 34d has an input pin that is provided for each loop coil LC end and two output pins that are provided for each input pin. With one end of a loop coil LC being referred to as an output terminal T1 and the other end as an output terminal T2 below, the switch 34d has one input pin for each of the output terminals T1 and T2. Each input pin is connected to an end of a corresponding loop coil LC via a let-out line PLx. The switch 34d fulfills a role of connecting each input pin with any one of the two corresponding output pins, in response to control by the sensor controller 35.

Each differential amplifier 34g is a circuit that amplifies the difference in potential between two input signals by a predetermined amplification rate to thereby generate an EMR-method received signal Rx_EMR, outputs the received signal Rx_EMR to the sensor controller 35, and is provided for each loop coil LC. One input terminal of a differential amplifier 34g is connected to the other of the two output pins that correspond to the output terminal T1 of the corresponding loop coil LC, and the other input terminal of the differential amplifier 34g is connected to the other of the two output pins that correspond to the output terminal T2 of the corresponding loop coil LC.

Each operational amplifier 34f is a circuit that amplifies the voltage difference between the input terminal and the ground terminal to thereby generate a capacitance-method received signal Rx_TP, outputs the received signal Rx_TP to the sensor controller 35, and is provided for each loop coil LC. The input terminal of the operational amplifier 34f is connected to both one of the two output pins that correspond to the output terminal T1 of the corresponding loop coil LC and one of the two output pins that correspond to the output terminal T2 of the corresponding loop coil LC. The operational amplifier 34f is provided with a parallel capacitor for removing high-frequency noise.

Described with reference to FIG. 2 in detail with regard to operation in a case where the sensor controller 35 detects the position of the passive pointer, the sensor controller 35 in this case first controls the switch 34d such that both ends of each loop coil LC are connected to each other and are connected in common to the input terminal of an operational amplifier 34f (a first state). Next, the sensor controller 35 controls the switch 34b such that each input pin is connected to the corresponding output pin. As a result, the touch detection signal Tx_TP is supplied from the sensor controller 35 to one end of each linear electrode EM in the x direction. In addition, the sensor controller 35 controls the switch 34c such that each input pin is separated from the corresponding ground pin, whereby the other end of each linear electrode EM in the x direction is set to the floating state.

Specific details of the touch detection signal Tx_TP generated by the sensor controller 35 can be expressed by a matrix A indicated in the following formula (3). The matrix A is a square matrix that has a plurality of rows that correspond one-to-one with the plurality of linear electrodes EM. The left one of a suffix added to each element (such as All) of the matrix A indicates the order of output from the sensor controller 35, and the right one indicates a serial number for a linear electrode EM. M represents the total number of linear electrodes EM. A specific value for each element is one of “1” or “−1.” The matrix A is desirably an orthogonal matrix, but does not need to be an orthogonal matrix.

$$\begin{matrix}[ Formula 3 ] & \\ A = ( \begin{matrix}{A}_{11} & {A}_{21} & {A}_{31} & … & {A}_{M 1} \\ {A}_{12} & {A}_{22} & {A}_{32} & … & {A}_{M 2} \\ {A}_{13} & {A}_{23} & {A}_{33} & … & {A}_{M 3} \\ ⋮ & ⋮ & ⋮ & … & ⋮ \\ {A}_{1 M} & {A}_{2 M} & {A}_{3 M} & … & {A}_{MM}\end{matrix} ) & ( 3 )\end{matrix}$$

The sensor controller 35 generates the touch detection signal Tx_TP for each column of the matrix A, and supplies the touch detection signal Tx_TP to each linear electrode EM. The touch detection signal Tx_TP according to a typical example is a binary pulse signal that becomes high in a case where the corresponding element of the matrix A is 1 and that becomes low in a case where the corresponding element is −1. A touch detection signal Tx_TP corresponding to one column in the matrix A is referred to below as a “partial touch detection signal Tx_TP.”

While supplying one partial touch detection signal Tx_TP to each linear electrode EM, the sensor controller 35 obtains a received signal Rx_TP that is supplied from each operational amplifier 34f. Letting the capacitance formed between the mth linear electrode EMₘ and the nth loop coil LCₙ be Cₘₙ, the partial touch detection signal Tx_TP that corresponds to the xth column of the matrix A is supplied to each linear electrode EM, and the received signal Rx_TP supplied to the sensor controller 35 from the nth operational amplifier 34f becomes a value indicated by the following formula (4).

$$\begin{matrix}[ Formula 4 ] & \\ \begin{matrix}( {A}_{x 1} & \begin{matrix}{A}_{x 2} & {A}_{x 3} & … & {A}_{xM} )\end{matrix}\end{matrix} ( \begin{matrix}{C}_{1 n} \\ {C}_{2 n} \\ {C}_{3 n} \\ ⋮ \\ {C}_{Mn}\end{matrix} ) & ( 4 )\end{matrix}$$

Accordingly, while supply of the partial touch detection signal Tx_TP corresponding to each column of the matrix A is executed, the received signal Rx_TP obtained for the nth loop coil LCₙ is, as a whole, expressed by a vector b that is indicated in the following formula (5).

$$\begin{matrix}[ Formula 5 ] & \\ b = A ( \begin{matrix}{C}_{1 n} \\ {C}_{2 n} \\ {C}_{3 n} \\ ⋮ \\ {C}_{Mn}\end{matrix} ) & ( 5 )\end{matrix}$$

The sensor controller 35 performs a calculation indicated by the left side in the following formula (6) on this vector b to thereby separately obtain the capacitance Cₘₙ for each linear electrode EM. However, a matrix A⁻¹ indicated in formula (6) is the inverse matrix of the matrix A. As indicated in the formula (6), the unit matrix I is achieved when the matrix A is multiplied by the matrix A⁻¹. Hence, the sensor controller 35 performs this calculation to thereby be able to separately obtain the capacitance Cₘₙ for the intersection point between each linear electrode EMₘ and the nth loop coil LCₙ, as indicated on the right side of formula (6).

$$\begin{matrix}[ Formula 6 ] & \\ {A}^{- 1} b = {A}^{- 1} A ( \begin{matrix}{C}_{1 n} \\ {C}_{2 n} \\ {C}_{3 n} \\ ⋮ \\ {C}_{Mn}\end{matrix} ) = I ( \begin{matrix}{C}_{1 n} \\ {C}_{2 n} \\ {C}_{3 n} \\ ⋮ \\ {C}_{Mn}\end{matrix} ) = ( \begin{matrix}{C}_{1 n} \\ {C}_{2 n} \\ {C}_{3 n} \\ ⋮ \\ {C}_{Mn}\end{matrix} ) & ( 6 )\end{matrix}$$

For each loop coil LC, the sensor controller 35 executes a calculation that is similar to formula (6) to thereby derive the capacitance Cₘₙ for each intersection point between the linear electrodes EM and the loop coils LC. The sensor controller 35 derives the position (a two-dimensional position) of the passive pointer, in reference to a distribution of the derived capacitance Cₘₙ within the panel surface 3a. Specifically, it is sufficient if a position corresponding to the apex of the distribution is derived as the position of the passive pointer.

Next, described in detail with reference to FIG. 3 regarding operation in a case where the sensor controller 35 detects the position of the electromagnetic resonance pen P, the sensor controller 35 in this case first controls the switch 34d such that the output terminals T1 and T2 of each loop coil LC are mutually connected to the input terminals of the differential amplifier 34g that respectively correspond thereto (a second state).

Next, the sensor controller 35 controls the switch 34a such that the alternating current i_{A} is supplied to two linear electrodes EMₘ₋₁ and EMₘ₋₂ that are adjacent to each other on one side of the linear electrode EMₘ, and the alternating current i is supplied to two linear electrodes EMₘ₊₁ and EMₘ₊₂ that are adjacent to each other on the other side of the linear electrode EMₘ. In addition, the sensor controller 35 controls the switch 34c such that each input pin is connected to the corresponding ground pin, whereby the other end of each linear electrode EM in the x direction is set to the grounded state.

As a result of this control, a pseudo coil centered on the linear electrode EMₘ is formed, and the sensor alternating magnetic field is generated on the panel surface 3a (in particular, above the linear electrode EMₘ). Generating a sensor alternating magnetic field in this manner is referred to below as “sending a sensor alternating magnetic field from the linear electrode EMₘ.” The sensor controller 35 is configured to execute a similar process while, excluding the four linear electrodes EM positioned at both ends of all linear electrodes EM, treating each linear electrode EM in order as the linear electrode EMₘ to thereby sequentially send a similar sensor alternating magnetic field from these linear electrodes EM.

Note that, in order to allow the position of the electromagnetic resonance pen P to be detected over the entirety of the panel surface 3a, it is desirable that the abovementioned four linear electrodes EM that are excluded from execution of the abovementioned process be arranged at positions that are outside of a detection region for the electromagnetic resonance pen P. In addition, in the present embodiment, alternating currents are supplied to two linear electrodes EM on both sides of the linear electrode EMₘ that sends the sensor alternating magnetic field, but each alternating current is only required to be supplied to a predetermined number, which is one or more, of linear electrodes EM. For example, the alternating currents may be supplied to one linear electrode EM on both sides or three or more linear electrodes EM on both sides.

While the sensor alternating magnetic field is being sent from the linear electrode EMₘ, the sensor controller 35 obtains the received signal Rx_EMR which is supplied from each differential amplifier 34g. The sensor controller 35 obtains the received signal Rx_EMR that is supplied from each differential amplifier 34g, while switching the linear electrode EMₘ that sends the sensor alternating magnetic field, to thereby obtain the received signal Rx_EMR for each intersection point between the loop coils LC and the linear electrodes EM. The position (two-dimensional position) of the electromagnetic resonance pen P is derived in reference to the distribution, within the panel surface 3a, of the reception strength of the received signals Rx_EMR that are obtained in this manner. Specifically, a position corresponding to the apex of the distribution may be derived as the position of the electromagnetic resonance pen P. In addition, the sensor controller 35 demodulates the received signal Rx_EMR that is received at the highest strength to thereby obtain data that is transmitted by the electromagnetic resonance pen P.

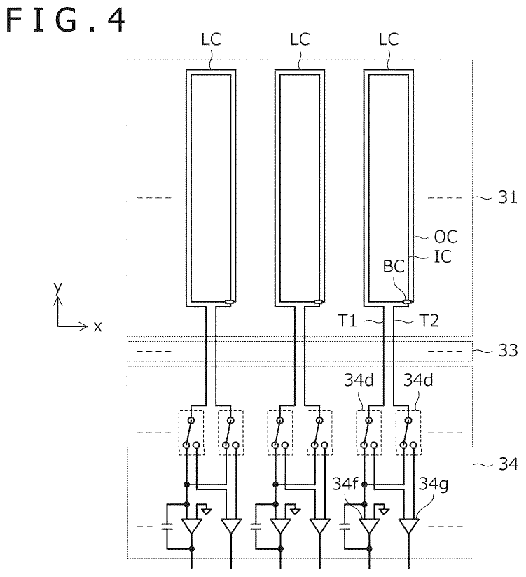

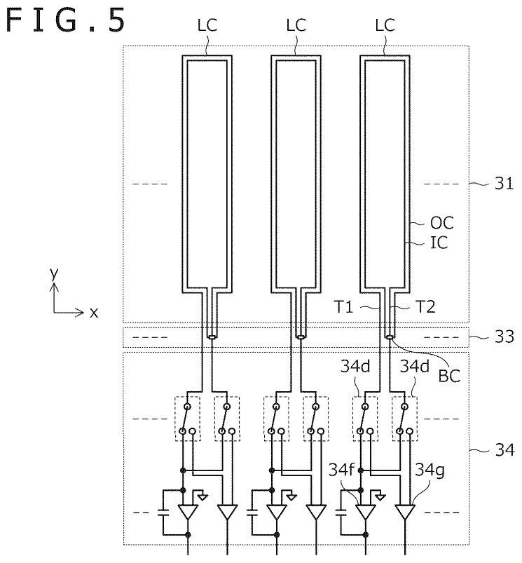

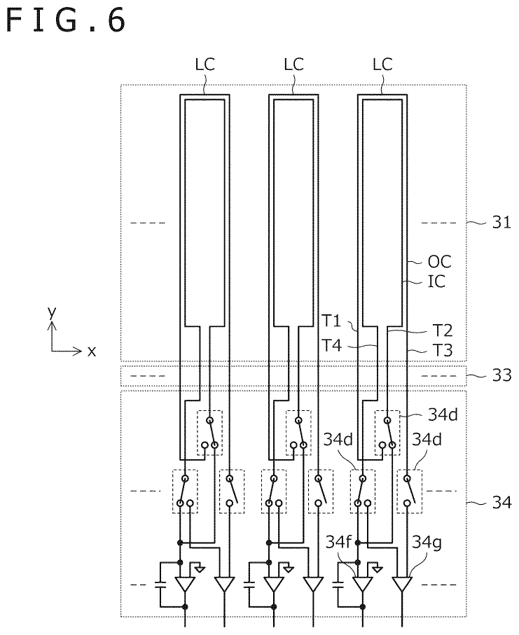

FIG. 4 is a view that illustrates a configuration of the sensor 31, the flexible substrate 33, and the switch unit 34 that are included in the position detection system 1 according to the present embodiment. FIG. 4 only illustrates three loop coils LC and an internal configuration of the flexible substrate 33 and the switch unit 34 that correspond thereto. In addition, each switch inside the switch unit 34 has entered a state of detecting the passive pointer. These points are similar for FIG. 5 and FIG. 6, which are mentioned below.

As illustrated in FIG. 4, each second electrode according to the present embodiment is configured by a two-winding loop coil LC. Described in detail, each loop coil LC includes an outside loop coil OC one end of which is connected to the output terminal T1 and an inside loop coil IC the other end of which is connected to the output terminal T2. The other end of the outside loop coil OC and one end of the inside loop coil IC are connected to each other by a bridge conductor BC that straddles the inside loop coil IC.

In plan view, the bridge conductor BC is disposed within a region in which the outside loop coil OC and the inside loop coil IC are formed (a region on the sensor 31 side with respect to the flexible substrate 33; referred to below as a “sensor region”), but, when seen in three dimensions, is formed in a layer that is different from a layer (an EMR sensor layer) in which the outside loop coil OC and the inside loop coil IC are provided. The bridge conductor BC and the other end of the outside loop coil OC are connected by a first via conductor that is provided penetrating an unillustrated interlayer insulating film. Similarly, the bridge conductor BC and the one end of the inside loop coil IC are connected by a second via conductor that is provided penetrating the unillustrated interlayer insulating film.

The layer in which the bridge conductor BC is provided may be the layer (a touch sensor layer) in which first electrodes included in the sensor 31 (for example, the linear electrodes EM illustrated in FIG. 2 and FIG. 3) are formed. In this manner, it becomes possible to form the bridge conductor BC without providing a new layer for the bridge conductor BC.

By virtue of the position detection system 1 according to the present embodiment as described above, the other end of the outside loop coil OC and the one end of the inside loop coil IC are connected to each other by the bridge conductor BC that straddles the inside loop coil IC. Thus, it becomes possible to provide the sensor 31 that has two-winding receiving coils. In addition to each loop coil LC having two windings, the configuration of the position detection system 1 according to the present embodiment is the same as the configuration illustrated in FIG. 2 and FIG. 3. Hence, the sensor 31 according to the present embodiment can be used for both the capacitance method and the EMR method, as described with reference to FIG. 2 and FIG. 3.

FIG. 5 is a view that illustrates a configuration of the sensor 31, the flexible substrate 33, and the switch unit 34 that are included in the position detection system 1 according to a first variation of the first embodiment. As understood upon comparing FIG. 5 with FIG. 4, each loop coil LC according to the present variation differs from each loop coil LC according to the first embodiment in that the bridge conductor BC that connects the other end of the outside loop coil OC with the one end of the inside loop coil IC is disposed on the flexible substrate 33 and not within the sensor region. Accordingly, the other end of the outside loop coil OC and the one end of the inside loop coil IC are each extended to the flexible substrate 33. By virtue of the present variation, in addition to being able to achieve a similar effect to that of the present embodiment, an effect of being able to omit a step for providing via conductors in the sensor region can be achieved.

FIG. 6 is a view that illustrates a configuration of the sensor 31, the flexible substrate 33, and the switch unit 34 that are included in the position detection system 1 according to a second variation of the first embodiment. As is understood by comparing FIG. 6 with FIG. 4, the sensor 31 according to the present variation differs from the sensor 31 according to the first embodiment in having four output terminals T1 through T4 for each loop coil LC. As in the first embodiment, the one end of the outside loop coil OC is connected to the output terminal T1 and the other end of the inside loop coil IC is connected to the output terminal T2. The output terminal T3 is connected to the other end of the outside loop coil OC, and the output terminal T4 is connected to the one end of the inside loop coil IC.

The switch 34d according to the present variation has one input pin and two output pins in relation to the output terminal T2, one input pin and one output pin in relation to the output terminal T3, and one input pin and two output pins in relation to the output terminal T4. One of the two output pins corresponding to the output terminal T2 is connected to the output terminal T1, and the other is connected to the input terminal of an operational amplifier 34f. The output pin corresponding to the output terminal T3 is connected to one input terminal of a differential amplifier 34g. One of the two output pins corresponding to the output terminal T4 is connected to the input terminal of the operational amplifier 34f, and the other is connected to the other input terminal of the differential amplifier 34g.

In a case of detecting the position of a passive pointer, the sensor controller 35 according to the present variation connects the input pin corresponding to the output terminal T2 to the other output pin (on the operational amplifier 34f side) and connects the input pin corresponding to the output terminal T4 to the one output pin (on the operational amplifier 34f side), as illustrated in FIG. 6. In addition, the sensor controller 35 separates the input pin corresponding to the output terminal T3 from the output pin. As a result, a state in which both ends of the inside loop coil IC are connected to each other and are connected in common to the input terminal of the operational amplifier 34f is established. Thus, the sensor controller 35 can detect the position of the passive pointer in a fashion similar to that in the first embodiment. In the present variation, the outside loop coil OC is not used to detect the position of the passive pointer.

In contrast, in a case of detecting the position of the electromagnetic resonance pen P, the sensor controller 35 according to the present variation connects the input pin corresponding to the output terminal T2 to the one output pin (on the output terminal T1 side), connects the input pin corresponding to the output terminal T3 to the output pin, and connects the input pin corresponding to the output terminal T4 to the other output pin (on the differential amplifier 34g side). As a result, a state in which a two-winding loop coil is formed between the one input terminal of the differential amplifier 34g and the other input terminal thereof is established. Accordingly, by virtue of the present variation, it also becomes possible to provide a sensor that has a two-winding receiving coil, and the sensor controller 35 will be able to detect the position of the electromagnetic resonance pen P in a fashion similar to that in the first embodiment.

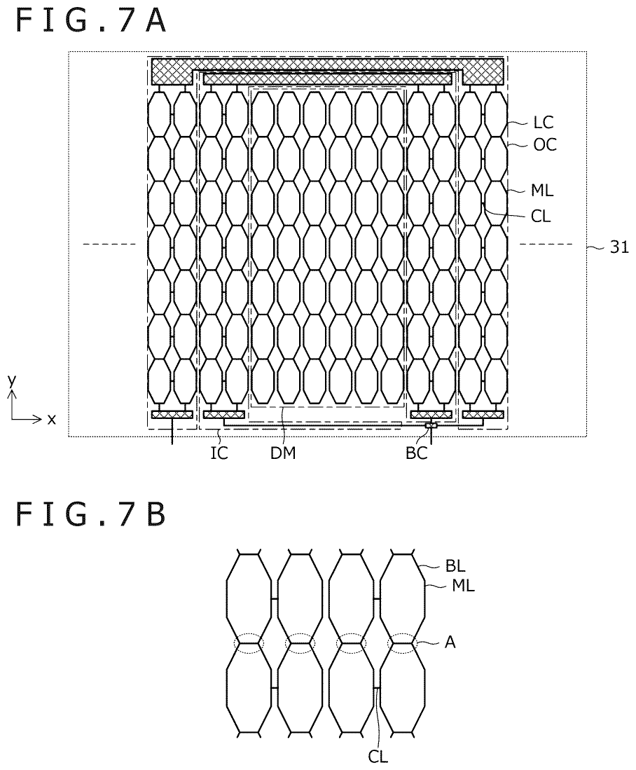

Next, description is given regarding a position detection system 1 according to a second embodiment of the present disclosure. FIGS. 7A and 7B are views that illustrate a configuration of a sensor 31 that is included in the position detection system 1 according to the present embodiment. The position detection system 1 according to the present embodiment differs from the position detection system 1 according to the first embodiment in that a loop coil LC that configures a second electrode included in the sensor 31 includes a mesh electrode. Other features are similar to those of the position detection system 1 according to the first embodiment. Therefore, description continues below while focus is placed on differences from the position detection system 1 according to the first embodiment.

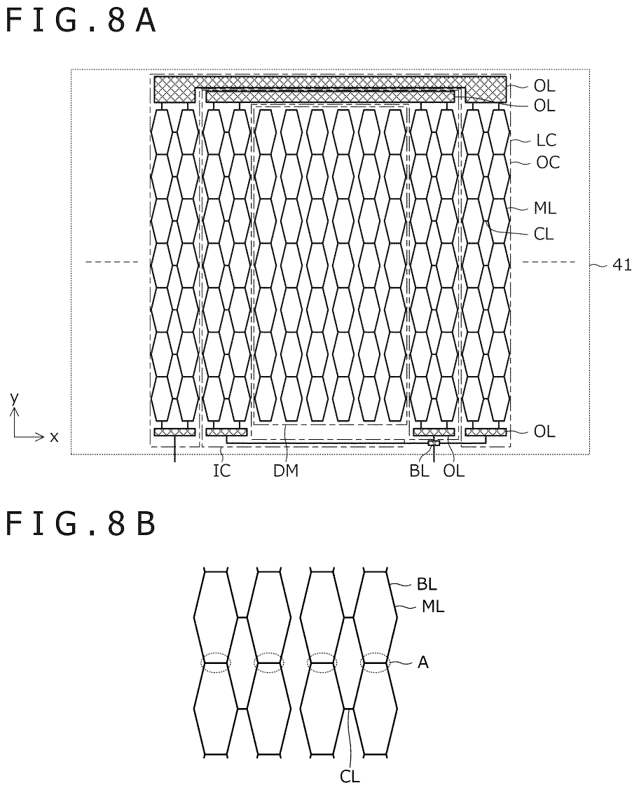

FIG. 7A illustrates one of a plurality of loop coils LC included in the sensor 31, as well as a dummy mesh electrode DM that is disposed at a central portion of the one loop coil LC. In addition, in FIG. 7A, an inner region of a plate-shaped conductor is indicated by hatching, and a conductor is assumed not to be formed in a portion that is surrounded by solid lines and is not hatched. These points are similar for FIG. 8A, which is mentioned later. In addition, FIG. 7B illustrates a partial enlarged view of the loop coil LC illustrated in FIG. 7A.

As illustrated in FIG. 7A, the sensor 31 according to the present embodiment includes a plurality of main wire sections ML that are conductors each formed into an octagon, and a plurality of connection sections CL that connect two adjacent main wire sections ML to one another. The plurality of main wire sections ML are arranged in a matrix, and one side of the loop coil LC is configured by two columns of main wire sections ML. Described in detail in line with the example illustrated in FIG. 7A, in order from the left side, one side of the outside loop coil OC is configured by two columns of main wire sections ML, one side of the inside loop coil IC is configured by the next two columns of main wire sections ML, the dummy mesh electrode DM is configured by the next six columns of main wire sections ML, the other side of the inside loop coil IC is configured by the next two columns of main wire sections ML, and the other side of the outside loop coil OC is configured by the next two columns of main wire sections ML. Each connection section CL fulfills a role of connecting main wire sections ML that are adjacent in the x direction within the same side. Note that the loop coil LC according to the present embodiment is similar to the loop coil LC according to the first embodiment in that the other end of the outside loop coil OC and one end of the inside loop coil IC are connected to each other by a bridge conductor BC that straddles the inside loop coil IC.

Each side of each main wire section ML is configured by a linear partial wire BL that is illustrated in FIG. 7B. A main wire section ML according to the present embodiment is an octagon as described above, and is thus configured by eight partial wires BL. One of a plurality of partial wires BL that configure each of the main wire sections ML that are not the main wire sections ML positioned at both ends of the matrix in the y direction also serves as one of a plurality of partial wires BL that configure another main wire section ML that is adjacent in the y direction (regions A illustrated in FIG. 7B). This makes it possible to reduce the direct-current resistance of the loop coil LC in comparison to a case where main wire sections ML that are adjacent in the y direction are connected to each other at a single point via a thin wire such as the connection section CL.

By virtue of the position detection system 1 according to the present embodiment as described above, it becomes possible to use a mesh electrode to configure a loop coil LC similar to that of the position detection apparatus 3 according to the first embodiment. In comparison to a case of using a conventional mesh electrode in which main wire sections ML adjacent in the y direction are connected to each other at a single point, it is possible to realize loop coils LC having low direct-current resistance even though the loop coils LCs are configured by mesh electrodes.

FIGS. 8A and 8B are views that illustrate a configuration of a sensor 31 that is included in a position detection system 1 according to a variation of the second embodiment. The position detection system 1 according to the present variation differs from the position detection system 1 according to the second embodiment in that the main wire sections ML are hexagons instead of octagons, but is otherwise similar to the position detection system 1 according to the second embodiment. As described above, the main wire sections ML are not limited to octagons, and may be various polygonal shapes, such as quadrilaterals or rhomboids in addition to the hexagons illustrated in FIGS. 8A and 8B. However, when there is an open end, it is possible for the direct-current resistance to increase. Therefore, it is desirable for the main wire sections ML to be closed shapes.

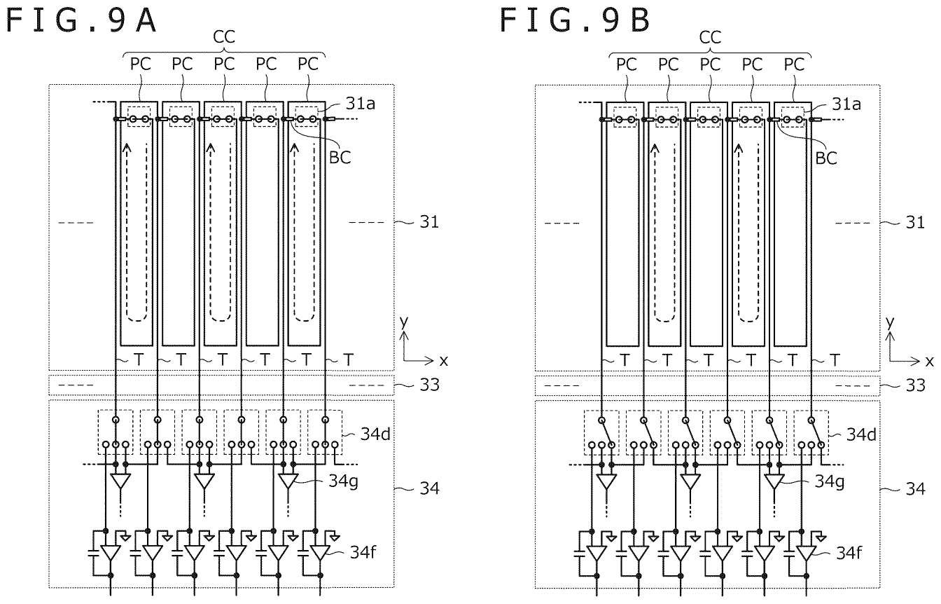

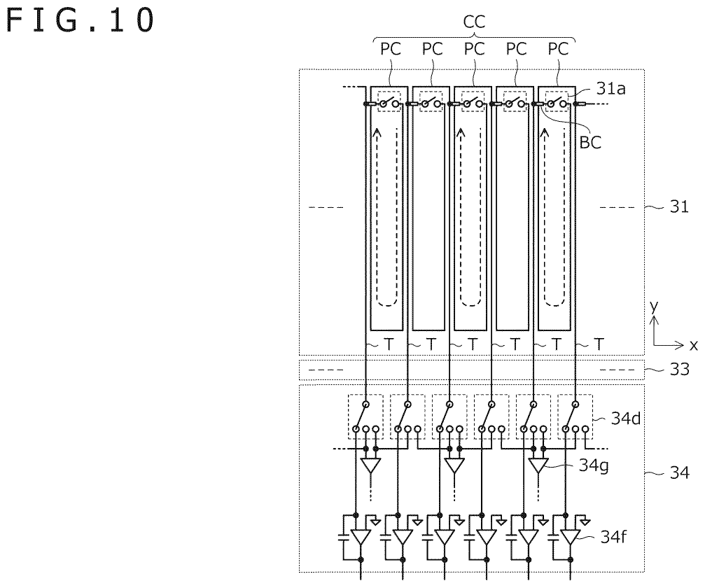

Next, description is given regarding a position detection system 1 according to a third embodiment of the present disclosure. FIGS. 9A, 9B, and 10 are each a view that illustrates a configuration of a sensor 31, a flexible substrate 33, and a switch unit 34 that are included in the position detection system 1 according to the present embodiment. The position detection system 1 according to the present embodiment differs from the position detection system 1 according to the first embodiment in that the plurality of second electrodes included in the sensor 31 are configured by a composite coil CC that has similar electrical characteristics to a comb-shaped coil described above. Other features are similar to those of the position detection system 1 according to the first embodiment. Therefore, description continues below while focus is placed on differences from the position detection system 1 according to the first embodiment.

First, described with reference to FIG. 9A, the sensor 31 according to the present embodiment has a plurality of output terminals T and a composite coil CC that includes a partial coil PC provided for each output terminal T.

The number of windings for each partial coil PC is 1.5. Each partial coil PC is connected to an output terminal T at an end that is provided at the outermost circumference on the flexible substrate 33 side, and the other end of the partial coil PC is connected, via a bridge conductor BC that straddles the partial coil PC, to the outermost circumference of another partial coil PC that is adjacent in the x direction.

A switch 31a that is configured to be able to be turned on and off by control from the sensor controller 35 is provided near the bridge conductor BC for each partial coil PC. In a case where the switches 31a are off, the partial coils PC enter a state of being electrically separated.

Each switch 34d according to the present embodiment has an input pin that is provided for each output terminal T and three output pins that are provided for each input pin. In the present embodiment, one differential amplifier 34g is provided for every two switches 34d. With a serial number added as a subscript character as exemplified by the switches 34d1 and 34d2 from one side in the x direction, one input terminal of a differential amplifier 34gₙ is connected in common to the third output pin of a switch 34d2n-1 and the second output pin of a switch 34d2n, and the other input terminal of the differential amplifier 34gₙ is connected in common to the third output pin of the switch 34d2n and the second output pin of the switch 34d₂ₙ₊₁. Operational amplifiers 34f are provided at a ratio of one for each switch 34d, and the input terminal of each operational amplifier 34f is connected to the first output pin of the corresponding switch 34d.

In a case of detecting the position of a passive pointer, the sensor controller 35 according to the present embodiment controls each switch 34d such that the output terminals T are connected to the input terminals of the operational amplifiers 34f and sets all switches 31a to off, as illustrated in FIG. 10. As a result, one end of each partial coil PC is connected to the input terminal of the operational amplifier 34f, and the other end of the partial coil PC is set to a disengaged state. Thus, the sensor controller 35 will be able to detect the position of a passive pointer, as in the first embodiment.

In contrast, in a case of detecting the position of the electromagnetic resonance pen P, the sensor controller 35 according to the present embodiment, in a state of controlling all switches 31a to be on, controls the switches 34d between two states: the state illustrated in FIG. 9A and the state illustrated in FIG. 9B. In the state illustrated in FIG. 9A, the sensor controller 35 controls the switches 34d such that the output terminal Ten is connected to one input terminal of the differential amplifier 34gₙ and the output terminal T₂ₙ₊₁ is connected to the other input terminal of the differential amplifier 34gₙ. As a result, as illustrated by broken lines in FIG. 9A, a two-winding receiving coil is formed in the partial coil PC that corresponds to the output terminal T2n, and the pen alternating magnetic field is detected by this receiving coil.

In contrast, in the state illustrated in FIG. 9B, the sensor controller 35 controls the switches 34d such that the output terminal T2n-1 is connected to the one input terminal of the differential amplifier 34gₙ and the output terminal T2n is connected to the other input terminal of the differential amplifier 34gₙ. As a result, as illustrated by broken lines in FIG. 9B, a two-winding receiving coil is formed in the partial coil PC that corresponds to the output terminal T2n-1, and the pen alternating magnetic field is detected by this receiving coil.

The action of the composite coil CC as above is nothing but the action of a comb-shaped coil. In the composite coil CC, each receiving coil has two windings (a 1.5-winding partial coil PC+one side of an adjacent partial coil PC). Accordingly, it can be said that the position detection system 1 according to the present embodiment makes it possible to improve the reception sensitivity of the receiving coil while utilizing the advantages of a comb-shaped coil.

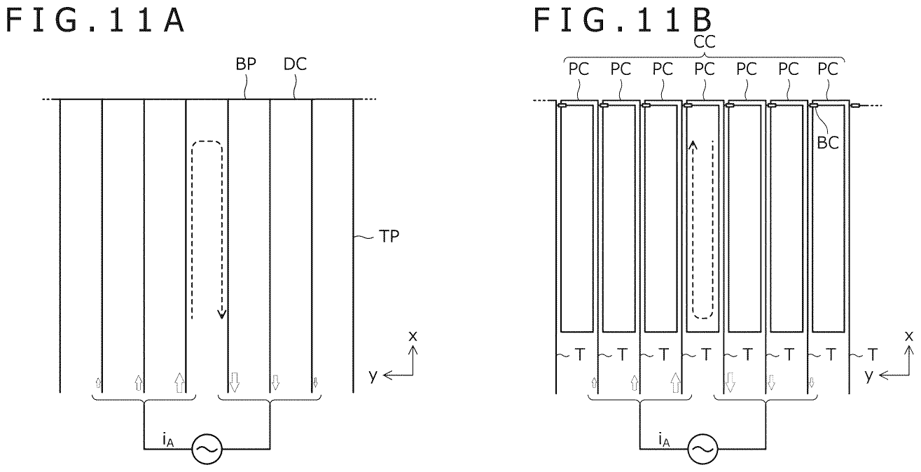

The composite coil CC as described in the present embodiment can also be used as the plurality of first electrodes instead of being used only as the plurality of second electrodes in the sensor 31, as a result of which the effect of being able to increase the level of detection for the electromagnetic resonance pen P in comparison to a case of using comb-shaped coils as the plurality of first electrodes can be achieved. With reference to FIG. 11A through FIG. 13B, description is given below in detail regarding this point.

FIG. 11A is a view that illustrates a case in which the plurality of first electrodes that are included in the sensor 31 are configured by a comb-shaped coil DC, and FIG. 11B is a view that illustrates a case in which the plurality of first electrodes that are included in the sensor 31 are configured by the composite coil CC.

As illustrated in FIG. 11A, the comb-shaped coil DC in the case of configuring the plurality of first electrodes has a shape where a plurality of comb teeth TP protrude in the x direction from a linear base section BP that extends in the y direction. This is nothing but a shape resulting from mutually connecting the other ends in the x direction of the plurality of linear electrodes EM illustrated in FIG. 2 to a linear conductor. In this case, there is no need to use both of the alternating currents i_{A} and is described in the first embodiment. For example, the alternating current i_{A} is supplied to one or more (three in FIG. 11A) comb teeth TP (referred to below as “transmitting comb teeth TP” when plural and a “transmitting comb tooth TP” when singular) that are adjacent to each other and received by one or more (three in FIG. 11A) comb teeth TP (referred to below as “receiving comb teeth TP” when plural and a “receiving comb tooth” when singular) that are adjacent to each other, whereby it is possible to send a sensor alternating magnetic field from a region that is between the transmitting comb tooth TP and the receiving comb tooth TP as illustrated by a broken line in FIG. 11A.

This also applies to the composite coil CC. As illustrated in FIG. 11B, for example, the alternating current i_{A} is supplied to one or more (three in FIG. 11B) output terminals T (referred to as “transmitting terminals T” below) that are adjacent to each other and received by one or more (three in FIG. 11B) output terminals T (referred to as “receiving terminals T” below) that are adjacent to each other, whereby it is possible to send the sensor alternating magnetic field from a partial coil PC that is positioned between the transmitting terminal T and the receiving terminal T as illustrated by a broken line in FIG. 11B.

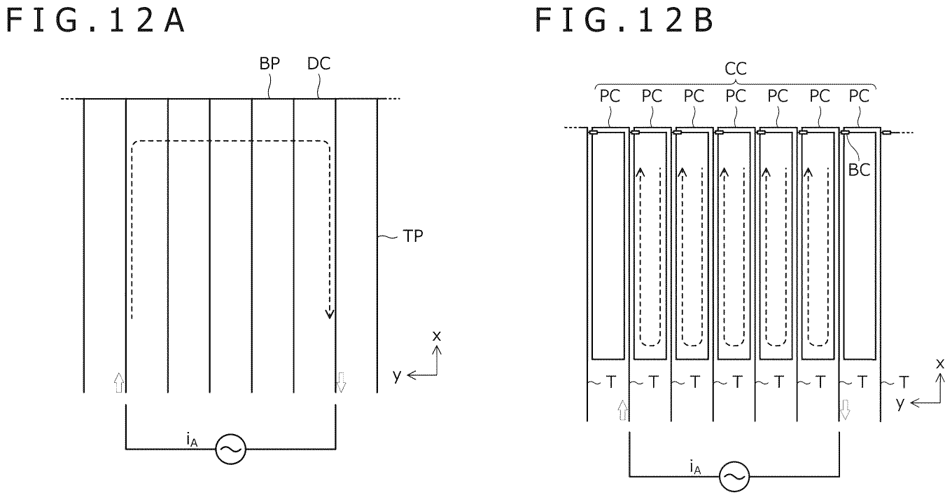

FIG. 12A is a view that illustrates a case in which the plurality of first electrodes included in the sensor 31 are configured by a comb-shaped coil DC, similarly to FIG. 11A, but differs from the example in FIG. 11A in that there is one transmitting comb tooth TP and a receiving comb tooth TP is separated from the transmitting comb tooth TP by four comb teeth. In the example in FIG. 12A, a sensor alternating magnetic field is also sent from the region between the transmitting comb tooth TP and the receiving comb tooth TP, but the sensor alternating magnetic field is sent from a wide range because the transmitting comb tooth TP and the receiving comb tooth TP are separated from each other.

In addition, FIG. 12B is a view that illustrates a case in which the plurality of first electrodes included in the sensor 31 are configured by a composite coil CC, similarly to FIG. 11B, but differs from the example in FIG. 11B in that there is one transmitting terminal T and a receiving terminal T is separated from the transmitting terminal T by four output terminals. In the example in FIG. 12B, a sensor alternating magnetic field is also sent from a partial coil PC that is between the transmitting terminal T and the receiving terminal T, but there is a plurality of partial coils PC between the transmitting terminal T and the receiving terminal T. Therefore, a sensor alternating magnetic field is sent from each of these partial coils PC, and, as a result thereof, the sensor alternating magnetic field is sent from a wide range.

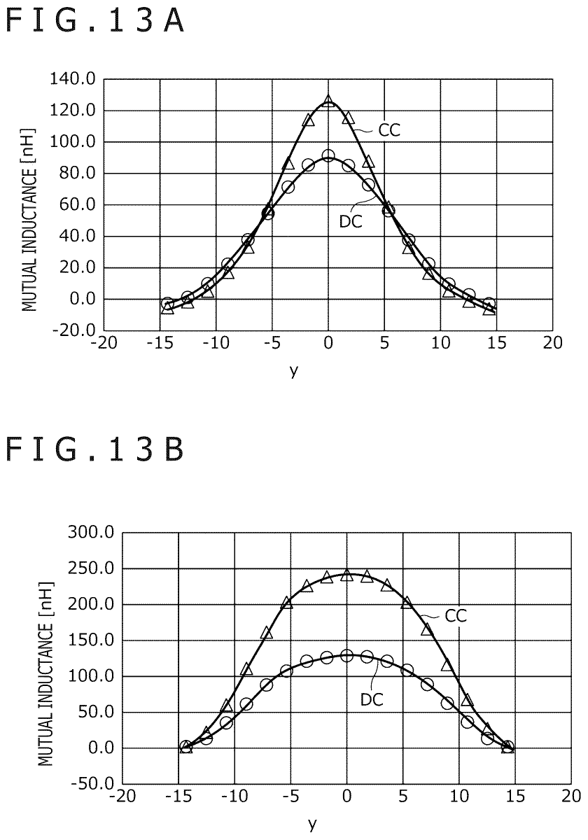

FIG. 13A is a view that illustrates the strength of sensor alternating magnetic fields that have been sent in the manner illustrated in FIGS. 11A and 11B, and FIG. 13B is a view that illustrates the strength of sensor alternating magnetic fields that have been sent in the manner illustrated in FIGS. 12A and 12B. The horizontal axis in each of FIG. 13A and FIG. 13B indicates y coordinates, and the vertical axis indicates the mutual inductance between a coil inside the electromagnetic resonance pen P and either the comb-shaped coil DC or composite coil CC inside the sensor 31. In both of FIGS. 13A and 13B, the y coordinate for the peak position of the sent sensor alternating magnetic field is set to 0.

From the results in FIGS. 13A and 13B, in both a case where the range for sending the sensor alternating magnetic field is relatively narrow and a case where the range is relatively wide, it is understood that a greater mutual inductance is achieved by sending from the composite coil CC in comparison to a case of sending from the comb-shaped coil DC. Accordingly, it can be said that it becomes possible to increase the level of detection for the electromagnetic resonance pen P by configuring the plurality of first electrodes included in the sensor 31 by the composite coil CC in comparison to a case of configuring the plurality of first electrodes by the comb-shaped coil DC.

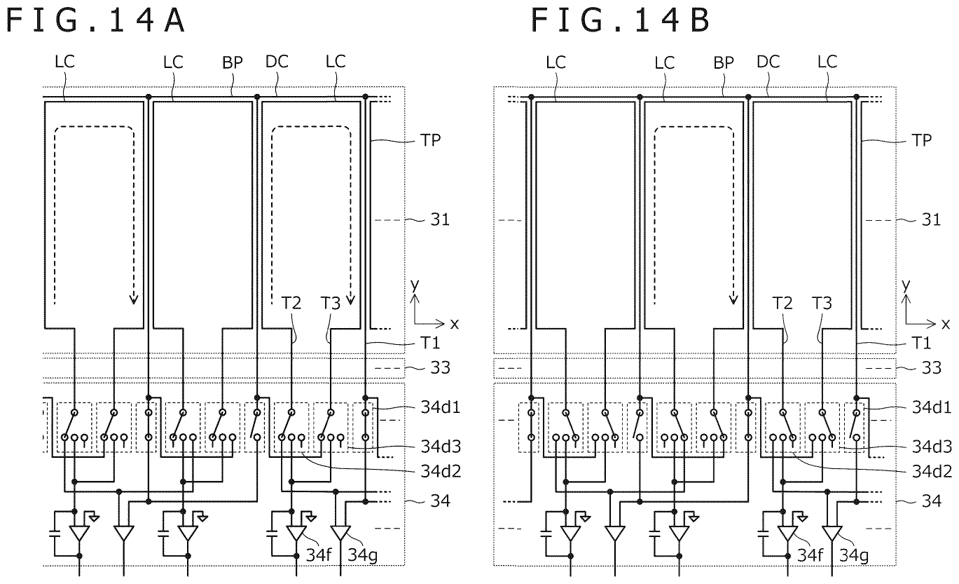

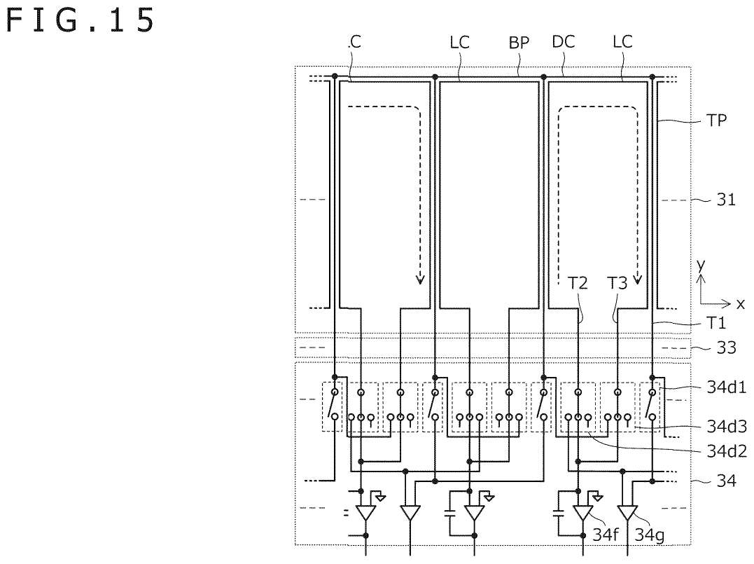

Next, description is given regarding a position detection system 1 according to a fourth embodiment of the present disclosure. FIGS. 14A, 14B, and 15 are each a view that illustrates a configuration of a sensor 31, a flexible substrate 33, and a switch unit 34 that are included in the position detection system 1 according to the present embodiment. The position detection system 1 according to the present embodiment differs from the position detection system 1 according to the third embodiment in that the plurality of second electrodes included in the sensor 31 are configured by a combination of a comb-shaped coil DC and loop coils LC. Other features are similar to those of the position detection system 1 according to the third embodiment. Therefore, description continues below while focus is placed on differences from the position detection system 1 according to the third embodiment.

First, described with reference to FIG. 14A, the sensor 31 according to the present embodiment has a comb-shaped coil DC that includes a base section BP that extends in the x direction and a plurality of comb teeth TP that each extend in the y direction, one end of each of the plurality of comb teeth TP being connected to the base section BP and the other end of each of the plurality of comb teeth TP configuring an output terminal T1, and a plurality of loop coils LC, each of which is provided between two adjacent comb teeth TP. One end of each loop coil LC configures an output terminal T2, and the other end configures an output terminal T3.

In place of a switch 34d, a switch unit 34 according to the present embodiment has a switch 34d1 that is provided for each output terminal T1, a switch 34d2 that is provided for each output terminal T2, and a switch 34d3 that is provided for each output terminal T3. Each switch 34d1 is an on-off switch that has an input pin that is connected to the corresponding output terminal T1 and one output pin. Each switch 34d2 has an input pin that is connected to the corresponding output terminal T2 and three output pins. Similarly, each switch 34d3 has an input pin that is connected to the corresponding output terminal T3 and three output pins. With a subscript character used to add a serial number as exemplified by switches 34d3₁ and 34d3₂ from one side in the x direction, the third output pin of each of switches 34d2₂ₐ and 34d3₂ₙ as well as the first output pin of each of switches 34d2₂ₙ₊₁ and 34d3₂ₙ₊₁ are open ends that are not connected to anywhere. In addition, the first output pin of the switch 34d3₂ₙ is connected to the output terminal T₂ₙ, and the third output pin of the switch 34d3₂ₙ₊₁ is connected to the output terminal T₂ₙ₊₁.

In the present embodiment, one operational amplifier 34f is provided for each loop coil LC, and one differential amplifier 34g is provided for two output terminals T1. The input terminal of the operational amplifier 34f is connected in common to the second output pins of the corresponding switches 34d2 and 34d3. One input terminal of the differential amplifier 34gₙ is connected in common to the first output pin of a switch 34d2₂ₙ and the third output pin of a switch 34d2₂ₙ₊₁, and the other input terminal of the differential amplifier 34gₙ is connected in common to the output pin of a switch 34d1₂ₙ₊₁ and the output pin of a switch 34dl2_{n+2.}

In a case of detecting the position of a passive pointer, the sensor controller 35 according to the present embodiment, as indicated in FIG. 15, controls all of the switches 34d1 to be off, but controls each of the switches 34d2 and 34d3 such that the output terminals T2 and T3 are connected to the input terminals of the operational amplifiers 34f. As a result, a state in which both ends of a loop coil LC are connected to the input terminal of each operational amplifier 34f is established. Thus, the sensor controller 35 will be able to detect the position of the passive pointer, as in the first embodiment. In the present embodiment, the comb-shaped coil DC is not used to detect the position of the passive pointer.

In contrast, in a case of detecting the position of the electromagnetic resonance pen P, the sensor controller 35 according to the present embodiment controls the switches 34d1, 34d2, and 34d3 between two states: the state illustrated in FIG. 14A and the state illustrated in FIG. 14B. In the state illustrated in FIG. 14A, the sensor controller 35 controls each switch 34d1 such that the output terminal T1₂ₙ₊₁ is connected to the other input terminal of the differential amplifier 34gₙ but the output terminal T1₂ₙ₊₂ is separated from the other input terminal of the differential amplifier 34gₙ, controls each switch 34d2 such that the output terminal T2₂ₙ is connected to the one input terminal of the differential amplifier 34gₙ but the output terminal T2₂ₙ₊₁ is separated from the one input terminal of the differential amplifier 34gₙ, and controls each switch 34d3 such that the output terminal T3₂ₙ is connected to the output terminal T1₂ₙ but the output terminal T3₂ₙ₊₁ is separated from the output terminal T1₂ₙ₊₁. As a result, as indicated by broken lines in FIG. 14A, a two-winding receiving coil is formed by a comb tooth TP2₂ₙ, a loop coil LC₂ₙ, and a comb tooth TP2₂ₙ₊₁, and the pen alternating magnetic field will be detected by this receiving coil.

In contrast, in the state illustrated in FIG. 14B, the sensor controller 35 controls each switch 34d1 such that the output terminal T1₂ₙ₊₂ is connected to the other input terminal of the differential amplifier 34gₙ and the output terminal T1₂ₙ₊₁ is separated from the other input terminal of the differential amplifier 34gₙ, controls each switch 34d2 such that the output terminal T2₂ₙ₊₁ is connected to the one input terminal of the differential amplifier 34gₙ but the output terminal T2₂ₙ is separated from the one input terminal of the differential amplifier 34gₙ, and controls each switch 34d3 such that the output terminal T3₂ₙ₊₁ is connected to the output terminal T1₂ₙ₊₁ but the output terminal T3₂ₙ is separated from the output terminal T1₂ₙ. As a result, as indicated by a broken line in FIG. 14B, a two-winding receiving coil is formed by a comb tooth TP2₂ₙ₊₁, a loop coil LC₂ₙ₊₁, and a comb tooth TP22ₙ₊₂, and the pen alternating magnetic field will be detected by this receiving coil.

In the present embodiment as described above, it is also possible to obtain an action similar to that of a comb-shaped coil, and each receiving coil will have two windings (a one-winding loop coil LC+the comb teeth on both sides). Hence, even by the position detection system 1 according to the present embodiment, it can be said that it will be possible to increase the reception sensitivity of a receiving coil while utilizing the advantages of a comb-shaped coil, as with the position detection apparatus 3 according to the third embodiment.

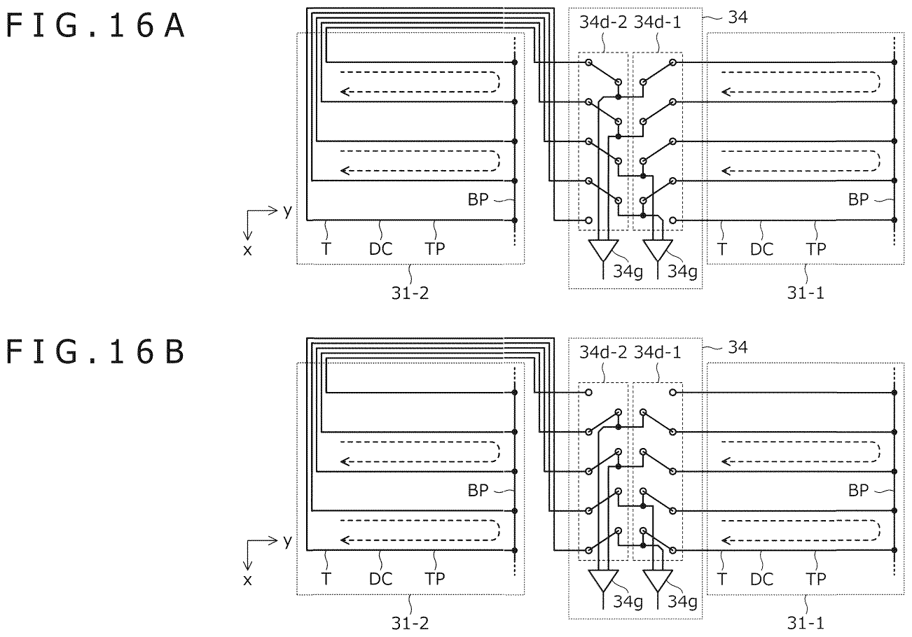

Next, description is given regarding a position detection system 1 according to a fifth embodiment of the present disclosure. FIGS. 16A and 16B are views that illustrate a configuration of sensors 31-1 and 31-2 as well as a switch unit 34 that are included in the position detection system 1 according to the present embodiment. The position detection system 1 according to the present embodiment is an above-described two-screen electronic device, and has two panel surfaces 3a. The sensor 31-1 is disposed for one of these two panel surfaces 3a, and the sensor 31-2 is disposed for the other of these two panel surfaces 3a.

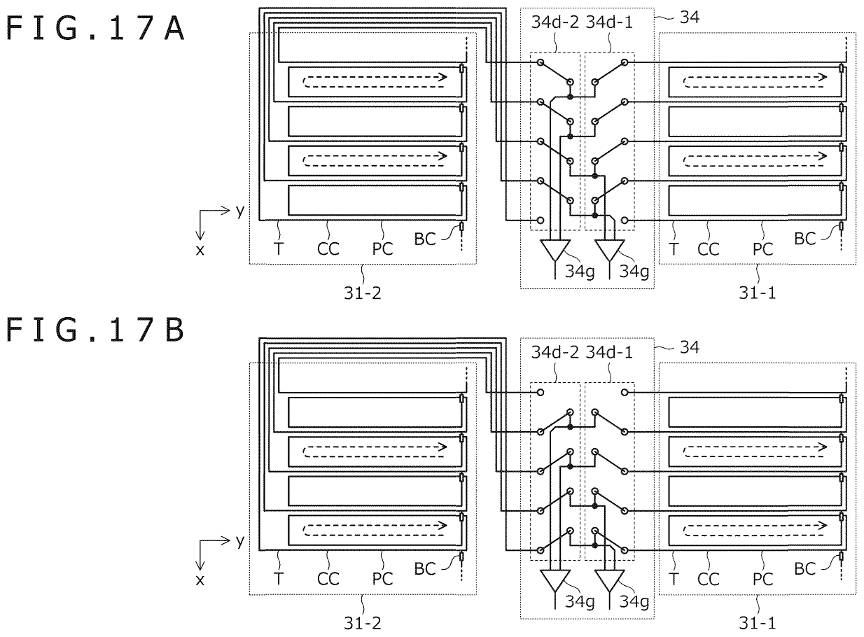

FIGS. 16A and 16B illustrate only one portion of a plurality of second electrodes included in the sensors 31-1 and 31-2, as well as a configuration inside the switch unit 34 that corresponds thereto. In addition, in FIGS. 16A and 16B, drawing of a configuration that relates to the detection of a passive pointer is omitted. These points similarly apply in later-described FIGS. 17A and 17B, FIGS. 18A and 18B, and FIGS. 19A and 19B.

As illustrated in FIGS. 16A and 16B, the plurality of second electrodes included in each of the sensors 31-1 and 31-2 according to the present embodiment are each configured by a comb-shaped coil DC. The number of comb teeth TP in the comb-shaped coil DC included in the sensor 31-1 is the same value as the number of comb teeth TP in the comb-shaped coil DC included in the sensor 31-2. In addition, the comb teeth TP in the comb-shaped coil DC included in the sensor 31-1 and the comb teeth TP in the comb-shaped coil DC included in the sensor 31-2 are provided at the same position in the x direction.

The switch unit 34 according to the present embodiment has two switch units 34d-1 and 34d-2 that respectively correspond to the sensors 31-1 and 31-2. The switch unit 34d-1 has input pins that correspond to the output terminals T of the comb-shaped coil DC in the sensor 31-1 and output pins that are one less than the input pins. The switch unit 34d-2 has input pins that correspond to the output terminals T of the comb-shaped coil DC in the sensor 31-2 and output pins that are one less than the input pins. The output pins in the switch unit 34d-1 and the output pins in the switch unit 34d-2 are mutually connected one-to-one in order from one side in the x direction.

In addition, the switch unit 34 according to the present embodiment has one differential amplifier 34g for two output pins in the switch unit 34d-1. One input terminal of the differential amplifier 34g is connected to one of the two corresponding output pins, and the other input terminal is connected to the other of the two corresponding output pins.

In a case of detecting the position of the electromagnetic resonance pen P, the sensor controller 35 according to the present embodiment controls the switch units 34d-1 and 34d-2 between two states: the state illustrated in FIG. 16A and the state illustrated in FIG. 16B. With a serial number added as a subscript character from one side in the x direction as with the output terminals T1 and T2, in the state illustrated in FIG. 16A, the sensor controller 35 controls the switches 34d such that the output terminal T2n-1 of each of the sensors 31-1 and 31-2 is connected to one input terminal of the differential amplifier 34gₙ and the output terminal Ten of each of the sensors 31-1 and 31-2 is connected to the other input terminal of the differential amplifier 34gₙ. As a result, as illustrated by broken lines in FIG. 16A, in each of the sensors 31-1 and 31-2, a one-winding receiving coil is formed between the output terminal T2n-1 and the output terminal T2n, and the pen alternating magnetic field will be detected by this receiving coil.

In contrast, in the state illustrated in FIG. 16B, the sensor controller 35 controls the switches 34d such that the output terminal Ten of each of the sensors 31-1 and 31-2 is connected to the one input terminal of the differential amplifier 34gₙ and the output terminal T₂ₙ₊₁ of each of the sensors 31-1 and 31-2 is connected to the other input terminal of the differential amplifier 34gₙ. As a result, as illustrated by broken lines in FIG. 16B, in each of the sensors 31-1 and 31-2, a one-winding receiving coil is formed between the output terminal T2n and the output terminal T₂ₙ₊₁, and the pen alternating magnetic field will be detected by this receiving coil.

By virtue of the position detection system 1 according to the present embodiment as described above, a receiving coil formed inside the sensor 31-1 and a receiving coil formed inside the sensor 31-2 are connected in parallel to one differential amplifier 34g (receiving circuit). Thus, it becomes possible to reduce the required number of receiving circuits in the two-screen electronic device in comparison to a case of providing a differential amplifier for each panel surface 3a.

FIGS. 17A and 17B are views that illustrate a configuration of the sensors 31-1 and 31-2 and the switch unit 34 that are included in the position detection system 1 according to a first variation of the fifth embodiment. The position detection system 1 according to the present variation differs from the position detection system 1 according to the fifth embodiment in the plurality of second electrodes included in each of the sensors 31-1 and 31-2 each being configured by a composite coil CC similar to that described in the third embodiment. Other features are similar to those of the position detection system 1 according to the fifth embodiment. Therefore, even in the position detection system 1 according to the present variation, the receiving coil formed inside the sensor 31-1 and the receiving coil formed inside the sensor 31-2 are connected in parallel to one differential amplifier 34g (receiving circuit). Accordingly, the position detection system 1 according to the present variation also makes it possible to reduce the required number of receiving circuits in a two-screen electronic device.

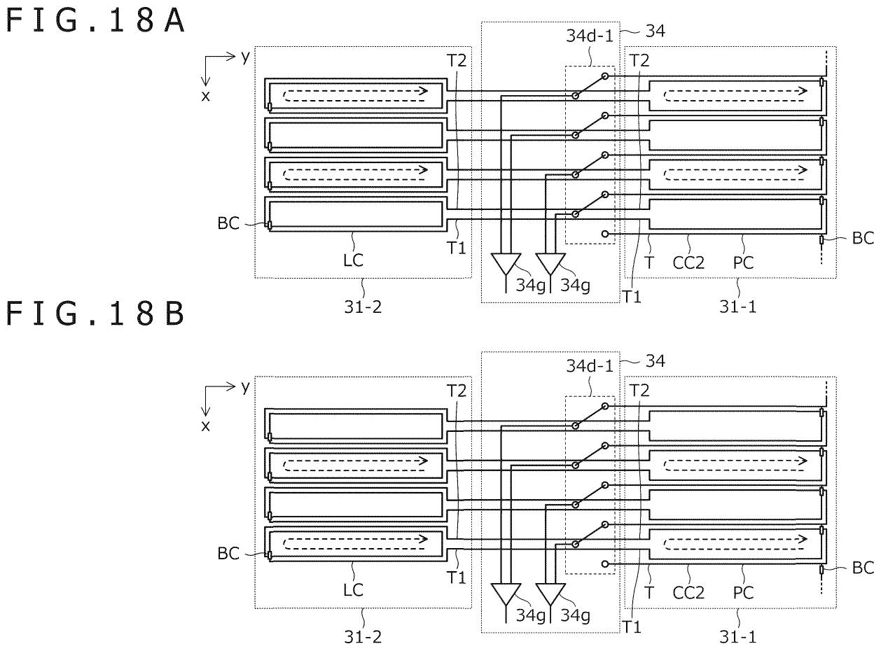

FIGS. 18A and 18B are views that illustrate a configuration of the sensors 31-1 and 31-2 and the switch unit 34 that are included in the position detection system 1 according to a second variation of the fifth embodiment. The position detection system 1 according to the present variation differs from the position detection system 1 according to the first variation in the plurality of second electrodes included in the sensor 31-2 being configured by loop coils LC similar to that described in the first embodiment.

Each partial coil PC inside the sensor 31-1 according to the present variation has an output terminal T that is provided at an outermost circumference and output terminals T1 and T2 that are obtained by dividing a short side on an inner-circumference sensor 31-2 side into two. The output terminal T1 in the partial coil PC is connected to the output terminal T1 of a corresponding loop coil LC inside the sensor 31-2, and the output terminal T2 of the partial coil PC is connected to the output terminal T2 of the corresponding loop coil LC inside the sensor 31-2.

The switch unit 34 according to the present variation has a switch unit 34d-1 that corresponds to the sensor 31-1, but lacks a switch unit 34d-2 that would correspond to the sensor 31-2. The configuration of the switch unit 34d-1 is similar to that of the switch unit 34d-1 according to the fifth embodiment.

Other features of the position detection system 1 according to the present variation are similar to those of the position detection system 1 according to the fifth embodiment. Therefore, even in the position detection system 1 according to the present variation, the receiving coil formed inside the sensor 31-1 and the receiving coil (the loop coil LC itself) formed inside the sensor 31-2 are connected to one differential amplifier 34g (receiving circuit). Accordingly, the position detection system 1 according to the present variation makes it possible to reduce the required number of receiving circuits in a two-screen electronic device. In the present variation, two receiving coils are connected in series to one differential amplifier 34g. Therefore, the position detection system 1 according to the present variation makes it also possible to reduce the size of the switch 34b in comparison to the position detection system 1 according to the fifth embodiment.

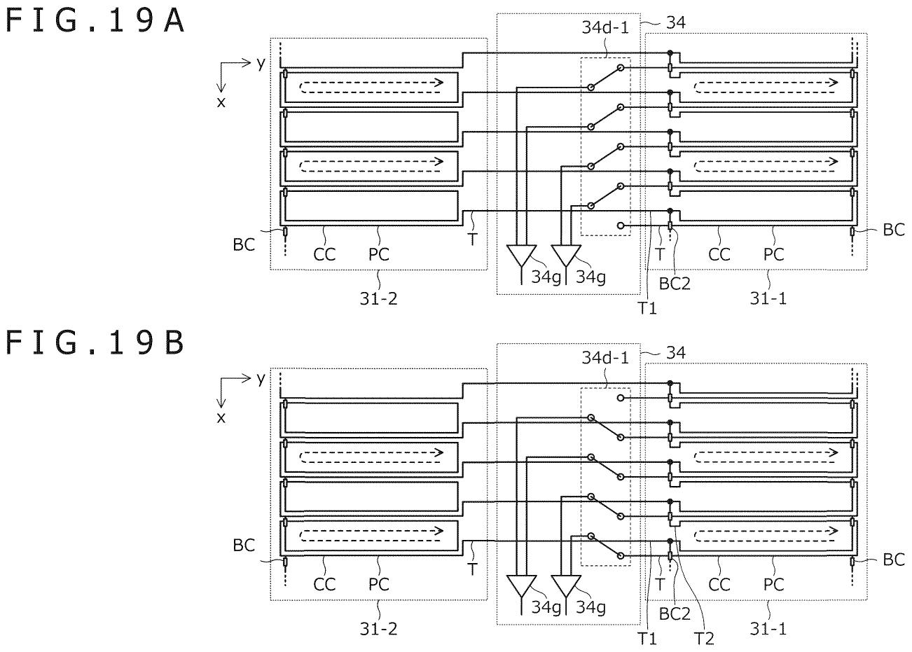

FIGS. 19A and 19B are views that illustrate a configuration of the sensors 31-1 and 31-2 and the switch unit 34 that are included in the position detection system 1 according to a third variation of the fifth embodiment. The position detection system 1 according to the present variation is similar to the position detection system 1 according to the first variation in the plurality of second electrodes included in each of the sensors 31-1 and 31-2 each being configured by a composite coil CC similar to that described in the third embodiment, but differs from the position detection system 1 according to the first variation in that the composite coil CC in the sensor 31-1 and the composite coil CC in the sensor 31-2 are directly connected.

In order to realize the abovementioned direct connection, each partial coil PC in the composite coil CC in the sensor 31-1 according to the present variation has an output terminal T1 that is provided at an outermost circumference as well as output terminals T1 and T2 that are obtained by dividing a short side on an inner-circumference sensor 31-2 side into two, similarly to the partial coil PC according to the second variation. The output terminal T1 of the partial coil PC is connected to the corresponding output terminal T inside the sensor 31-2, and the output terminal T2 of the partial coil PC is connected, via a bridge conductor BC2, to the adjacent output terminal T inside the sensor 31-1.

Similarly to the switch unit 34 according to the second variation, the switch unit 34 according to the present variation has a switch unit 34d-1 that corresponds to the sensor 31-1, but lacks a switch unit 34d-2 that would correspond to the sensor 31-2. The configuration of the switch unit 34d-1 is similar to that of the switch unit 34d-1 according to the fifth embodiment.

Other features of the position detection system 1 according to the present variation are similar to those of the position detection system 1 according to the fifth embodiment. Therefore, even in the position detection system 1 according to the present variation, the receiving coil formed inside the sensor 31-1 and the receiving coil (the loop coil LC itself) formed inside the sensor 31-2 are connected to one differential amplifier 34g (receiving circuit). Accordingly, the position detection system 1 according to the present variation makes it possible to reduce the required number of receiving circuits in a two-screen electronic device. In addition, in the present variation, two receiving coils are connected in series to one differential amplifier 34g. Therefore, the position detection system 1 according to the present variation makes it also possible to reduce the size of the switch 34b in comparison to the position detection system 1 according to the present embodiment.

Description has been given above regarding desirable embodiments of the present disclosure, but the present disclosure is in no way limited to such embodiments and it goes without saying that the present disclosure can be implemented in diverse modes within a scope that does not deviate from the substance of such embodiments.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A sensor comprising:
an outside loop coil having a first end and a second end, wherein the first end of the outside loop coil is connected to a first output terminal; and
an inside loop coil having a first end and a second end wherein the second end of the inside loop coil is connected to a second output terminal,
wherein the second end of the outside loop coil and the first end of the inside loop coil are connected to each other by a bridge conductor that straddles the inside loop coil.

2. The sensor according to claim 1, further comprising:
a flexible substrate in which is formed wiring that connects, to an integrated circuit, wiring inside a sensor region in which the outside loop coil and the inside loop coil are formed,
wherein the bridge conductor is disposed in the sensor region.

3. The sensor according to claim 2, wherein:
the sensor region includes:
an electromagnetic resonance-type sensor layer in which the outside loop coil and the inside loop coil are formed, and
a touch sensor layer in which a linear electrode used to detect a touch is formed, the bridge conductor is disposed in the touch sensor layer, and
a first end of the bridge conductor is connected by a first via conductor to the second end of the outside loop coil, and a second end of the bridge conductor is connected by a second via conductor to the first end of the outside loop coil.

4. The sensor according to claim 1, further comprising:
a flexible substrate in which is formed wiring that connects, to an integrated circuit, wiring inside a sensor region in which the outside loop coil and the inside loop coil are formed,
wherein the bridge conductor is disposed on the flexible substrate.

5. A position detection apparatus comprising:
a sensor including:
an outside loop coil having a first end and a second end, wherein the outside loop coil is connected to a first output terminal; and
an inside loop coil having a first end and a second end, wherein the outside loop coil is connected to a second output terminal, and wherein the second end of the outside loop coil and the first end of the inside loop coil are connected to each other by a bridge conductor that straddles the inside loop coil; and
a switch that, in operation, switches between a first state in which the first output terminal and the second output terminal are connected to each other and a second state in which the first output terminal and the second output terminal are respectively connected to a first input terminal and a second input terminal of a same differential amplifier.

6. A sensor controller for detecting a position of an electromagnetic resonance pen or a passive pointer by using a sensor including an outside loop coil having a first end and a second end, the first end of the outside loop coil being connected to a first output terminal, and an inside loop coil having a first end and a second end, the second end of the inside loop coil being connected to a second output terminal, and the second end of the outside loop coil and a first end of the inside loop coil being connected to each other by a bridge conductor that straddles the inside loop coil, the sensor controller comprising:
a processor;
a memory storing instructions that, when executed by the processor, cause a switch to switch between a first state in which the first output terminal and the second output terminal are connected to each other and a second state in which the first output terminal and the second output terminal are respectively connected to a first input terminal and a second input terminal of a same differential amplifier is controlled.
